(19) United States
(12) Patent Application Publication
(10) Pub. No.: US 2012/0217846 A1
(43) Pub. Date: Aug. 30, 2012

(54) Crystal Device

(75) Inventor: TAKEHIRO TAKAHASHI, SAITAMA (JP)

(73) Assignee: NIHON DEMPA KOGYO CO., LTD., TOKYO (JP)

(21) Appl. No.: 13/400,549

(22) Filed: Feb. 20, 2012

(30) Foreign Application Priority Data
Feb. 25, 2011 (JP) 2011-039130

(51) Int. Cl. H01L 41/053

(52) U.S. Cl. 310/346

(57) ABSTRACT

A surface-mount type crystal device is provided, having a rectangular crystal element including an excitation part and a frame surrounding the excitation part, wherein the frame has sides respectively along a first and a second directions intersected with each other; a rectangular base, bonded to a principal plane of the frame, having sides respectively along the first and the second directions; a rectangular lid, bonded to another principal plane of the frame, having sides respectively along the first and the second directions. A first and a second bonding materials, respectively corresponding to a thermal expansion coefficient in the first and the second directions of the crystal element, are respectively applied on the sides of the first and the second directions of each of the frame of a crystal material, the base and the lid. A second bonding material is different from the first bonding material.

### CROSS-REFERENCE TO RELATED APPLICATIONS

This application claims the priority benefit of Japan application serial no. 2011-039130, filed on Feb. 25, 2011. The entirety of the above-mentioned patent application is hereby incorporated by reference herein and made a part of this specification.

### FIELD OF THE INVENTION

This invention relates to a crystal device of surface-mount type.

### BACKGROUND OF THE INVENTION

For various electronic devices, such as cell phones, multiple crystal devices of surface-mount type are used in one electronic device. In order to meet the demands of downsizing electronic devices and further reducing the manufacturing cost, it is desired to reduce the size of the crystal devices and also the manufacturing cost. Therefore, various crystal devices of surface-mount type and the manufacturing methods thereof are proposed. As the crystal devices are miniaturized, not only the area occupied by an electric substrate is reduced, the thickness thereof is also desired to be reduced. Many crystal devices of surface-mount type are formed by bonding a crystal-oscillating crystal element with a base and a lid (cover). As for the crystal-oscillating crystal element, as the base and the lid become thinner, the differences in the thermal expansion coefficients among these materials become the reason of frequency variation due to separation, damage or distortion of the bonded portions.

In Patent Reference 1, a buffer layer is formed on a bonding material, and the thermal expansion coefficient of the buffer layer is set to be equal to an intermediate value between the thermal expansion coefficients of the crystal-oscillating crystal element and the sealing plate (the lid), so as to prevent separation and damage of the bonded portions. Besides, in Patent Reference 2, separation and damage of the bonded portions are prevented by setting the thermal expansion coefficient of the bonding material equal to the thermal expansion coefficient of the base or the lid, or the intermediate value between the thermal expansion coefficients of the base and the lid.

### PRIOR DOCUMENTS

### Patent References

[Patent Reference 1] Japan Unexamined Utility Model Application No. 02-150829 U

[Patent Reference 2] Japan Unexamined Patent Application No. 2008-271093

### SUMMARY OF THE INVENTION

### Technical Problem

However, according to the crystal device disclosed in Patent Reference 1, for bonding the crystal-oscillating crystal element and the base and for bonding the crystal element and the lid, for instance, a first bonding material is applied on the crystal element and a second bonding material is applied on the base. Then, the buffer layer is formed between the first bonding material and the second bonding material. Therefore, the manufacturing cost becomes expensive because of these increased processes.

Also, the crystal device disclosed in Patent Reference 2 applies a bonding material with a thermal expansion coefficient being the same as the thermal expansion coefficient of the base or the lid or the intermediate value between the base and the lid. However, an issue of bonding with the crystal-oscillating crystal element is not considered.

Besides, according to the crystal devices disclosed in both Patent Reference 1 and Patent Reference 2, when the crystal element is bonded to the base and the crystal element is bonded to the lid, the thermal expansion coefficients in the direction along a longer side and the direction along the shorter side of the crystal element are different because the crystal axes are different in the directions along the longer and shorter sides. These Patent References 1 and 2 provide no consideration to this issue.

Considering the above, the invention provides a surface-mountable crystal device, wherein a crystal-oscillating crystal element is used as an excitation part, in order to lower costs and reduce damage or frequency variation due to a temperature change.

### Solution to Problem

According to the first aspect, a crystal device is provided, and the crystal device comprises a crystal element, a base and a lid. The crystal element has a rectangular shape, and is formed by a crystal material comprises an excitation part that vibrates by applying a voltage and a frame surrounding the excitation part, wherein the frame comprises sides respectively along a first direction and a second direction intersected with the first direction. The base has a rectangular shape, is bonded to a principal plane of the frame, and comprises sides respectively along the first direction and the second direction. The lid has a rectangular shape, is bonded to another principal plane of the frame, and comprises sides respectively along the first direction and the second direction. Further, a first bonding material corresponding to a thermal expansion coefficient in the first direction of the crystal element is applied on the side along the first direction of each of the frame, the base and the lid. Also, a second bonding material that is different from the first bonding material and corresponds to a thermal expansion coefficient in the second direction of the crystal element is applied the side along the second direction of each of the frame, the base and the lid.

According to the crystal device of the second aspect, in the above crystal device, the first bonding material has a thermal expansion coefficient that is equal to a thermal expansion coefficient in the first direction of the crystal element, or equal to an intermediate value between a thermal expansion coefficient in the first direction of the crystal element and a thermal expansion coefficient in the second direction of the base and the lid. The second bonding material has a thermal expansion coefficient that is equal to a thermal expansion coefficient in the second direction of the crystal element, or equal to an intermediate value between a thermal expansion coefficient along the second direction of the crystal element and a thermal expansion coefficient along the second direction of the base and the lid.

According to the crystal device of the third aspect, in the above crystal devices, the crystal element is an AT-cut crystal material, and the base and the lid are the AT-cut crystal material, a Z-cut crystal material or a glass material.

According to the crystal device of the fourth aspect, in the above crystal devices, the crystal element is the Z-cut crystal material, and the base and the lid are the AT-cut crystal material, the Z-cut crystal material or a glass material.

According to the crystal device of the fifth aspect, in the above crystal devices, the first bonding material and the second bonding material are a polyimide resin or a glass with melting point of below 500° C.

### Effects of Invention

In the crystal device of the invention, the first bonding material that is most suitable for the thermal expansion coefficient in the first direction of the crystal-oscillating crystal element and the second bonding material that is most suitable for the thermal expansion coefficient of the second direction are used. Therefore, a downsized and thinner crystal device of surface-mount type, in which damage or frequency variation caused by a temperature change is reduced, is provided, and the cost is also reduced.

### BRIEF DESCRIPTION OF THE DRAWINGS

FIG. 1 is an exploded diagram of a first crystal device 100.

FIG. 2 is a cross-sectional view along A-A line of FIG. 1.

FIG. 3A is a planar view of a lid 10.

FIG. 3B is a planar view of a first crystal element 20.

FIG. 3C is a planar view of a base 30.

FIG. 4A shows a first applying method of a first bonding material 51 and a second bonding material 52.

FIG. 4B shows a second applying method of the first bonding material 51 and the second bonding material 52.

FIG. 4C shows a third applying method of the first bonding material 51 and the second bonding material 52.

FIG. 5 is a flowchart of the manufacturing steps of the first crystal device 100.

FIG. 6 is a planar schematic view of a crystal wafer 20W of an AT-cut crystal substrate.

FIG. 7 is a planar schematic view of a base wafer 30W of a Z-cut crystal substrate.

FIG. 8 is a planar schematic view of a lid wafer 10W of the Z-cut crystal substrate.

FIG. 9 is an exploded diagram of a second crystal device 110.

### DESCRIPTION OF THE PREFERRED EMBODIMENT

The preferred embodiments of the invention are described below based on the accompanying drawings. Referring to the following descriptions, unless the descriptions specifically limit the invention, it should be noted that the scope of the invention is not limited to these embodiments.

### First Embodiment

### <The Structure of the First Crystal Device 100>

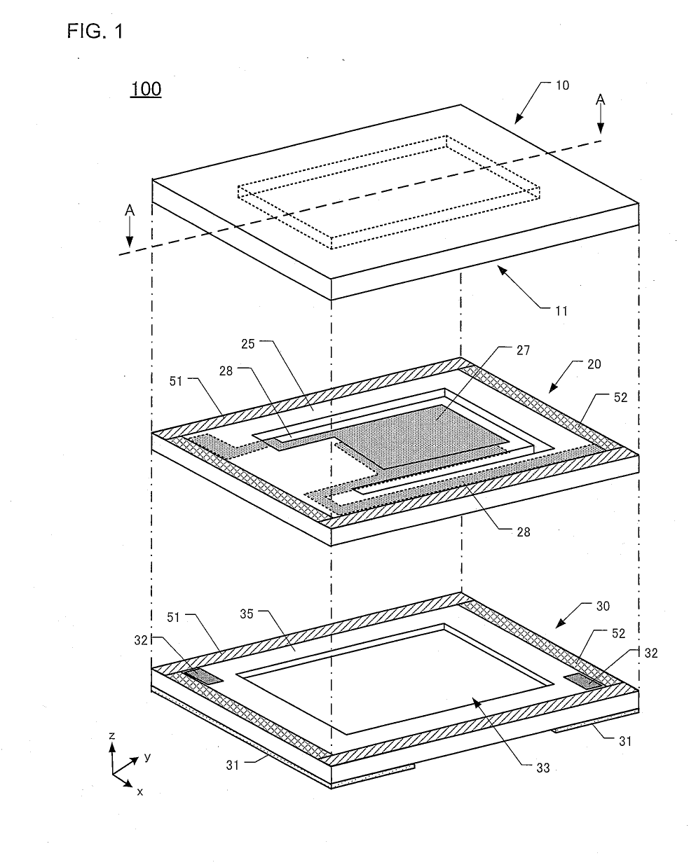

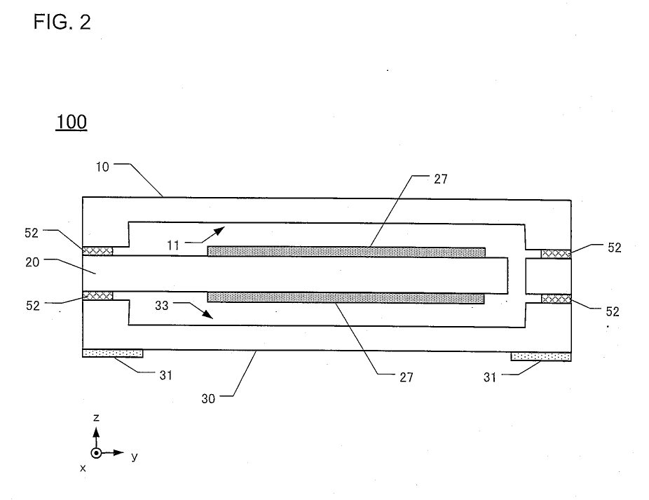

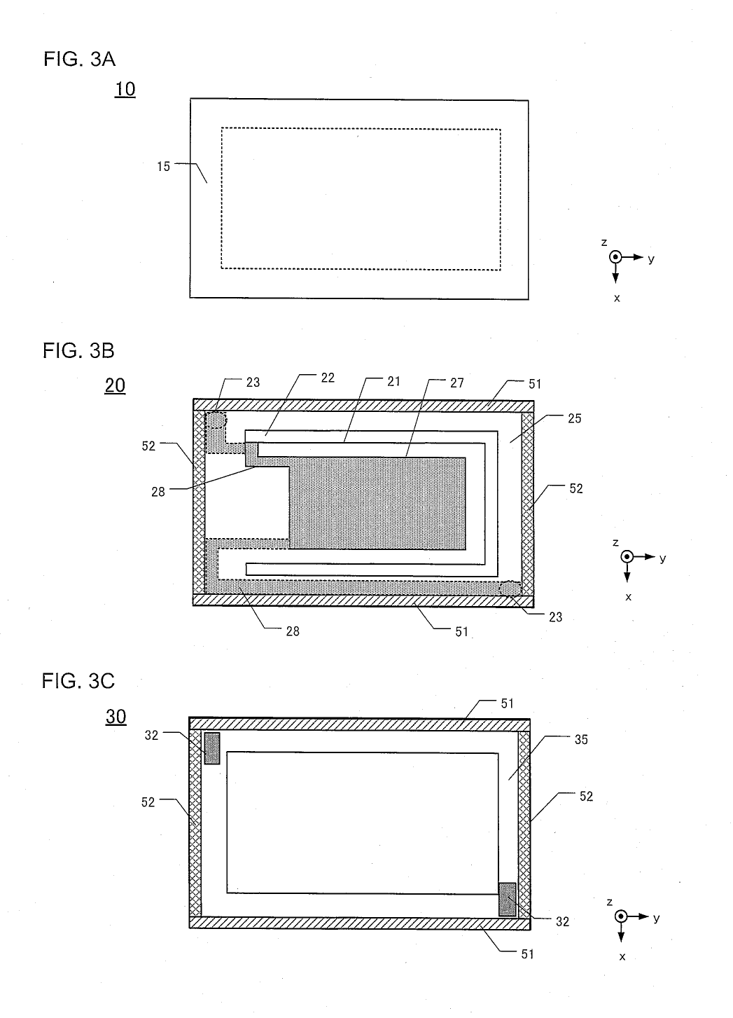

According to the first embodiment, the first crystal device 100 is a surface-mount type that is bonded with an electrical conductive material and further mounted to a surface of a printed substrate. The embodiment of the first crystal device 100 is described wherein an AT-cut crystal substrate is used as a crystal-oscillating first crystal element 20 and a Z-cut crystal substrate is used for a lid 10 and a base 30. The structure of the first crystal device 100 is described below with reference to FIGS. 1-3. FIG. 1 is an exploded diagram of the first crystal device 100, and FIG. 2 is a cross-sectional view along A-A line of FIG. 1. Also, FIG. 3A is a planar view of the lid 10, FIG. 3B is a planar view of the first crystal element 20, and FIG. 3C is a planar view of the base 30.

In this embodiment, a principal plane (YZ plane) of the AT-cut crystal substrate, as opposed to a Y-axis of crystal axes (XYZ), is tilted by 35°15′ with respect to a Y-axis of crystal axes (XYZ), from a Z-axis to the Y-axis direction by taking a X-axis as a center. However, in the specification, a direction of the longer side (hereinafter referred as “longer direction”) of the first crystal device 100 is described as a y-axis, a direction of the shorter side (hereinafter referred as “shorter direction”) is described as an x-axis, and a vertical direction is described as a z-axis.

As shown in FIG. 1, the first crystal device 100 includes the lid 10, the base 30 and the first crystal element 20. In the first crystal device 100, the lid 10 is disposed on an upper side (+z-axis side), the base 30 is disposed on a lower side (−z-axis side), and the first crystal element 20 is disposed between the lid 10 and the base 30. Also, external electrodes 31 are formed on a lower side of the base 30. Herefrom, the direction along the longer side of the first crystal device 100 is defined as a y-axis direction, the direction along the shorter side of the first crystal device 100 is defined as an x-axis direction, and the vertical direction of the first crystal device 100 is defined as a z-axis direction.

In the first crystal device 100 of this embodiment, a first bonding material 51 and a second bonding material 52 are applied to the upper side of the first crystal element 20. The first bonding material 51 and the second bonding material 52 are also applied to the upper surface of the base 30.

As shown in FIG. 2, the lid 10 and the first crystal element 20 are bonded by the second bonding material 52, and the first crystal element 20 and the base 30 are also bonded by the second bonding material 52. Moreover, though it is not shown in FIG. 2, the first bonding material 51 also, in the same way, bonds the lid 10 to the first crystal element 20, and the first bonding material 51 also bonds the first crystal element 20 to the base 30. And, the bonding methods for bonding the lid 10 to the first crystal element 20 and the first crystal element 20 to the base 30 will be described later.

As shown in FIG. 3A, the lid 10 has a rectangular principal plane, wherein the y-axis direction is parallel to the direction of the longer side of the rectangular principal plane and the x-axis direction is parallel to the shorter direction. As shown in FIG. 2, the principal planes of the lid 10 are formed, including a top surface that is the principal plane at the +z-axis side and a ceiling surface 11 that is the principal plane at the −z-axis side. A bonding surface 15 that is a surface for bonding to the first crystal element 20 is formed on a outer periphery of a surface at the −z-axis side. The lid 10 has a concavity (Refer to FIG. 2) that extends from the bonding surface 15 to the ceiling surface 11. Also, the lid 10 is formed by using the Z-cut crystal substrate as a base material.

As shown in FIG. 3B, the first crystal element 20 comprises an excitation part 21 wherein excitation electrodes 27 are formed thereon and a frame 25 is constructed to surround the periphery of the excitation part 21. Also, the excitation part 21 and the frame 25 are connected by a connection part 24. An extracting electrode 28 passes a part of an opening 22 and the frame 25, and is extracted to corners of the frame 25 on a bottom side of the first crystal element 20. The extracting electrode 28 is connected to electrode pads 23 on the corners of the frame 25 and to connection electrodes 32 (Refer to FIG. 1 and FIG. 3C) that are formed on the base 30. The electrodes formed on the first crystal element 20 are constructed by a chrome layer Cr formed on a crystal and a gold layer Au that is formed on the chrome layer Cr. Also, the first crystal element 20 is formed by using the AT-cut crystal substrate as a base material. The first bonding material 51 and the second bonding material 52 are also applied to the upper side of the outer periphery of the frame 25 of the first crystal element 20.

As shown in FIG. 3C, the base 30 has a rectangular principal plane wherein the y-axis direction is parallel to the longer direction and the x-axis direction is parallel to the shorter direction. As show in FIG. 1 and FIG. 2, the principal planes are formed with two surfaces, wherein one is a lower surface (the −z-axis side) that faces an outer part of the first crystal device 100 and the other is a bottom surface 33 (the +z-axis side) that faces an inside of the first crystal device 100 when the base 30 is assembled as a part of the first crystal device 100. In the outer periphery on the surface of the base 30 at the +z-axis side, a frame 35 is formed for bonding with the frame 25 of the first crystal element 20. The base 30 has a concavity (Refer to FIG. 1 and FIG. 2) that extends from the frame 35 to the bottom side 33. The connection electrodes 32 are formed on the frame 35 of the base 30, and the external electrodes 31 (Refer to FIG. 1 and FIG. 2) are formed on the lower surface. Also, the base 30 is formed by using the Z-cut crystal substrate as a base material. The first bonding material 51 and the second bonding material 52 are also applied to the upper side (the +z-axis side) of the outer periphery of the frame 35 of the base 30.

As mentioned above, the first crystal device 100 uses the Z-cut crystal substrate for the lid 10 and the base 30 and uses the AT-cut crystal substrate for the first crystal element 20. That is because the Z-cut crystal substrate is less expensive than the AT-cut crystal substrate and the cost of manufacturing the first crystal device 100 is reduced.

Also, by using the same crystal material for the lid 10, the first crystal element 20 and the base 30, when the lid 10 and the base 30 are bonded to the first crystal element 20 or when the surface mount process is performed for forming the first crystal device 100, the causes of frequency variation or break which results from the stress due to heating to nearly 400° C. can be reduced. However, it does not mean that the frequency change or the break caused by heat can be completely eliminated. Since a thermal expansion coefficient differs between the Z-cut crystal substrate and the AT-cut crystal substrate, the stress is applied between the lid 10 and the base 30 and the first crystal element 20, and the heat becomes the cause of the frequency change or the break. Moreover, the differences between the thermal expansion coefficients in the longer direction (the y-axis direction) and the shorter direction (the x-axis direction) of the first crystal element 20 formed by the AT-cut crystal substrate, or in the longer direction and the shorter direction of the lid 10 and the base 30 formed by the Z-cut crystal substrate are the causes of the frequency variation or the break.

The cause of the differences in the thermal expansion coefficients can be the differences in the crystal axes of a crystal substrate. The crystal substrate is formed from an artificial crystal, but the artificial crystal is formed by growing a crystalline crystal largely toward the z-axis direction by using an autoclave. The Z-cut crystal substrate is formed by cutting the artificial crystal along the Z-axis. Therefore, the crystal axes of the Z-cut crystal substrate are defined by the X-axis, Y-axis, and Z-axis (the longer direction, the shorter direction, and the vertical direction of the first crystal substrate are respectively defined as the y-axis direction, the x-axis direction, and the z-axis direction). In addition, the AT-cut crystal substrate is formed by cutting the artificial crystal along a direction that is rotated by 35°15′ from the Y-axis to the Z-axis by taking the X-axis as a rotation axis. Since the cutting directions of the Z-cut crystal substrate and the AT-cut crystal substrate are different, the thermal expansion coefficient in each axis direction differs from each other even though the Z-cut crystal substrate and the AT-cut crystal substrate are the same artificial crystal.

### [The Bonding Method and the Applying Method]

By using the crystal material for the first crystal element 20, the lid 10 and the base 30 for the first crystal device 100, influence of thermal expansion becomes less when the crystal materials are bonded or the first crystal device is bonded by the surface-mount method. However, when a temperature change is large, frequency variation or break may still occur on the first crystal device 100. By using a bonding material with a consideration of the thermal expansion coefficients in the longer and the shorter directions of the first crystal element 20, the lid 10 and the base 30, the first crystal device 100, the first crystal device 100 with less influence of the thermal expansion can be manufactured though under large temperature change.

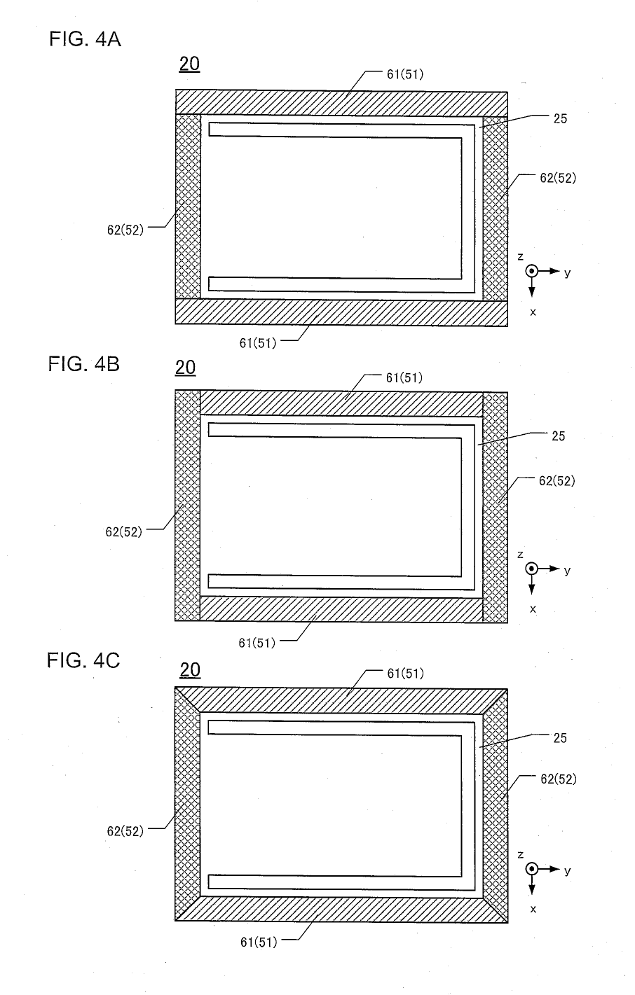

FIGS. 4A-4C show the applying area of the first bonding material 51 and the second bonding material 52 on the upper side (the +z-axis side) of the first crystal element 20 in order to bond the first crystal element 20 and the lid 10. In addition, for the sake of clearer understanding, the electrodes are not shown in the first crystal element 20 of FIGS. 4A-4C.

As shown in FIGS. 4A-4C, the first bonding material 51, having the same thermal expansion coefficient as that in the longer direction of the AT-cut crystal substrate, is applied in strips on the longer direction of the frame 25 (the first direction) of the first crystal element 20. Also, the second bonding material 52, having the same thermal expansion coefficient as that in the shorter direction of the AT-cut crystal substrate, is applied in strips on the shorter side of the frame 25 (the second direction) of the first crystal element 20.

There are three applying methods. FIG. 4A shows a first applying method, FIG. 4B shows a second applying method, and FIG. 4C shows a third applying method.

As shown in FIG. 4A, the first applying method is that, on the frame 25 of the first crystal element 20, the first bonding material 51 is applied on the first applying areas 61, each of which is spread over the entire length in the longer direction of the first crystal element 20, and the second bonding material 52 is applied on the second applying areas 62, each of which is spread over the shorter direction between the first applying areas 61.

As shown in FIG. 4B, the second applying method is that, on the frame 25 of the first crystal element 20, the second bonding material 52 is applied on the second applying areas 62, each of which is spread over the entire length in the shorter direction of the first crystal element 20, and the first bonding material 51 is applied on first applying areas 61, each of which is spread over the longer direction between the second applying areas 62.

As shown in FIG. 4C, the third applying method is that, on the frame 25 of the first crystal element 20, each of corners of the frame 25 is divided equally by the first bonding material 51 and the second bonding material 52. A joint section between the first applying area 61 and the second applying area 62 is formed by cutting ends of the first and the second applying areas 61 and 62 with at an angle of 45°.

The first bonding material 51 and the second bonding material 52 are formed by methods, for example, screen printing and so on. Also, a polyimide resin or a glass paste (a low melting point glass whose main raw material is vanadium) whose melting point is below 500° C. can be used as a material of the first bonding material 51 and the second bonding material 52. Because the polyimide resin may have different thermal expansion coefficient depending on a molecular structure thereof, the polyimide resins respectively having the same thermal expansion coefficients as those of the longer direction and the shorter direction of the AT-cut crystal substrate are chosen as the bonding material. Also, since the thermal expansion coefficient of the glass paste varies depending on the amount of filler that is added to the glass paste, the glass pastes that respectively have the same thermal expansion coefficients as those of the longer direction and the shorter direction of the AT-cut crystal substrate are chosen as the bonding material.

Besides, the first bonding material 51 that has a thermal expansion coefficient equal to an intermediate value of the thermal expansion coefficient along the longer direction of the AT-cut crystal substrate and the thermal expansion coefficient along the longer direction of the Z-cut crystal substrate can also be used. The second bonding material 52 that has a thermal expansion coefficient equal to an intermediate value of the thermal expansion coefficient along the shorter direction of the AT-cut crystal substrate and the thermal expansion coefficient along the shorter direction of the Z-cut crystal substrate are also used.

As described above, the bonding method for the first crystal element 20 and the lid 10 and the applying method for applying bonding material to the upper surface of the frame 25 of the first crystal element 20 are shown in this embodiment. However, the first crystal element 20 and the base 30 can be bonded by using the same bonding method and the upper surface of the frame 35 of the base 30 can be processed by the same applying method. Also, the first bonding material 51 or the second bonding material 52 is applied on the upper surface of the frame 25 of the first crystal element 20 in this embodiment; however, instead of being applied on the upper surface of the frame 25 of the first crystal element 20, the first bonding material 51 or the second bonding material 52 can be applied on the bonding surface 15 at the lid 10 side to bond the first crystal element 20 and the lid 10. In addition, instead of being applied on the upper surface of the frame 35 of the base 30, the first bonding material 51 or the second bonding material 52 can be applied on the lower surface of the frame 25 of the first crystal element 20 to bond the first crystal element 20 and the base 30.

### [The Manufacturing Method of the First Crystal Device 100]

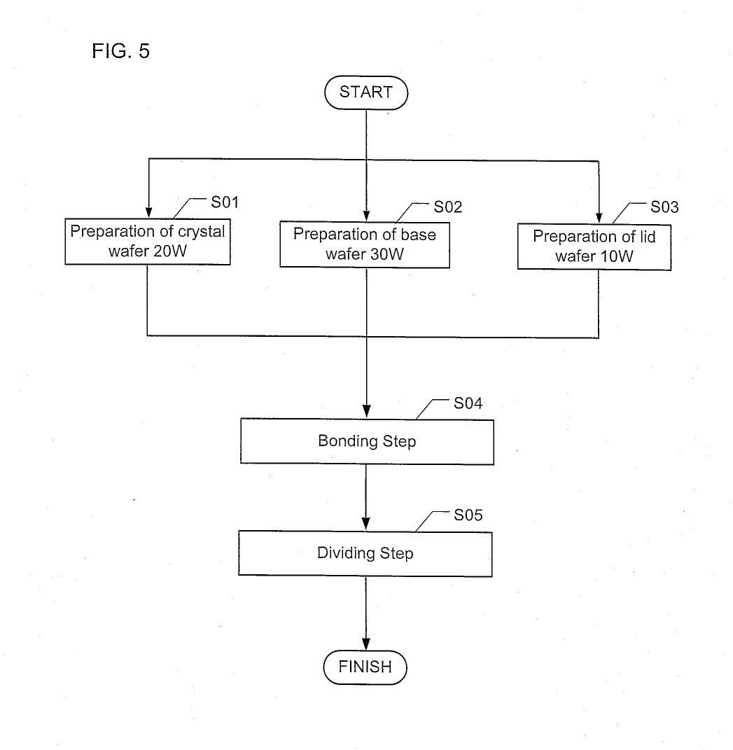

A manufacturing method for the first crystal device 100, wherein the Z-cut crystal substrate is used for the lid 10 and the base 30 and the AT-cut crystal substrate is used for the first crystal element 20, is described by referring to FIG. 5 to FIG. 8.

FIG. 5 is a flowchart of manufacturing steps of the first crystal device 100.

In the step S01, a crystal wafer 20W of the AT-cut crystal substrate is processed. In this process, the first crystal element 20 is formed on the crystal wafer 20W of the AT-cut crystal substrate.

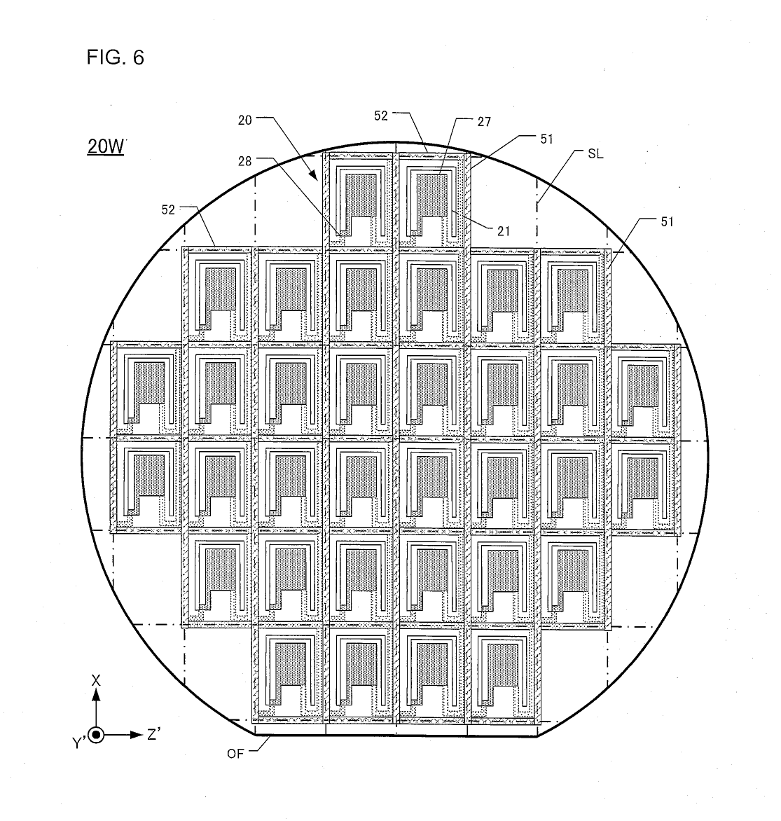

FIG. 6 is a planar schematic view of the crystal wafer 20W of the AT-cut crystal substrate. Because the first crystal element 20 is an AT-vibrating device, the AT-cut crystal substrate is used for the crystal wafer 20W. An orientation flat OF is formed in order to specify crystal orientation on a part of a margin of the crystal wafer 20W. A notch, instead of the orientation flat OF, can be formed on the crystal wafer 20W. A diameter of the crystal wafer 20W is, for instance, three inches or four inches. A plurality of the first crystal elements 20 shown in FIG. 3B is formed on the crystal wafer 20W. Meantime, to facilitate the explanation of this exemplary embodiment of the invention, thirty four first crystal elements 20 are drawn on the crystal wafer 20W in FIG. 6. However, for the actual manufacturing, hundreds or thousands of the first crystal elements 20 can be formed on one wafer. Also, as described in the drawing, the formation of the excitation electrodes 27 and the extracting electrodes 28 is carried out on the crystal wafer 20W, and the first bonding material 51 and the second bonding material 52 are applied on the crystal wafer 20W. Furthermore, the crystal axes of the AT-cut crystal substrate of this embodiment are formed by taking the longer direction of the first crystal element 20 as the X-axis, the shorter direction as the Z′-axis, and a direction perpendicular to the X-axis and the Z′-axis is taken as the Y′-axis.

In the step S02 of FIG. 5, a base wafer 30W of the Z-cut crystal substrate is processed. In this process, the base wafer 30W of the Z-cut crystal substrate is prepared.

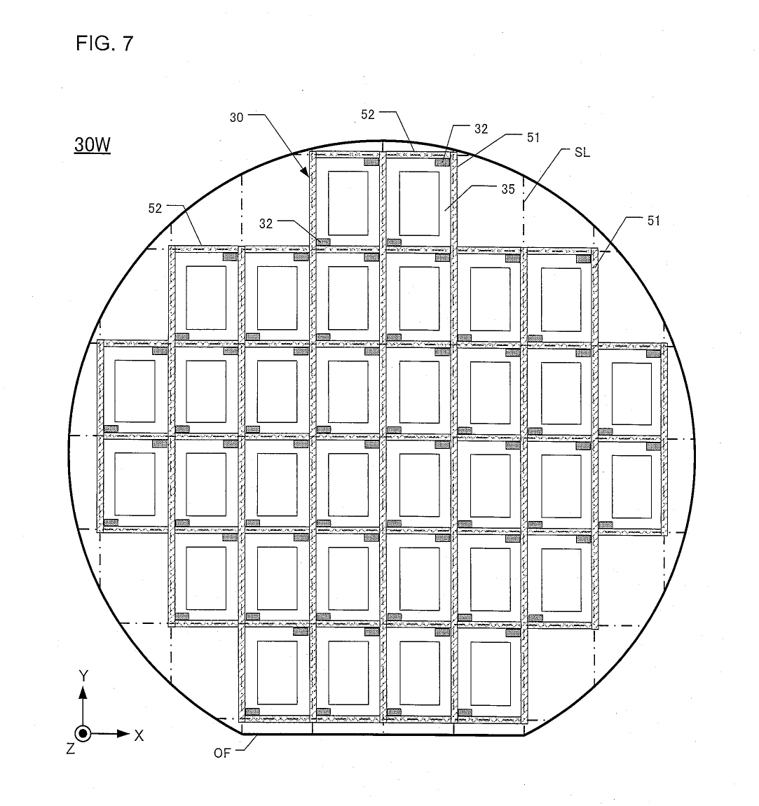

FIG. 7 is a planar schematic view of the base wafer 30W of the Z-cut crystal substrate. The Z-cut crystal substrate is used as the base material for the base wafer 30W, and the orientation flat OF is formed in order to specify the crystal orientation on a part of a margin of the crystal wafer 30W. A diameter of the base wafer 30W is also, for instance, three inches or four inches. A plurality of the bases 30 shown in FIG. 3C is formed on the base wafer 30W. Thirty four bases 30 are drawn on the base wafer 30W; however, for the actual manufacturing, hundreds or thousands of the bases 30 can be formed on one wafer. Also, as described in the drawing, a concavity is formed on a surface that faces the crystal wafer 20W on the base wafer 30W, and the frame 35 is formed around the concavity. In addition, the connection electrodes 32 and the external electrodes 31 are formed (Refer to FIG. 1 and FIG. 2), and the first bonding material 51 and the second bonding material 52 are applied.

In the step S03 of FIG. 5, a lid wafer 10W of the Z-cut crystal substrate is prepared. In this process, the lid wafer 10W of the Z-cut crystal substrate is prepared.

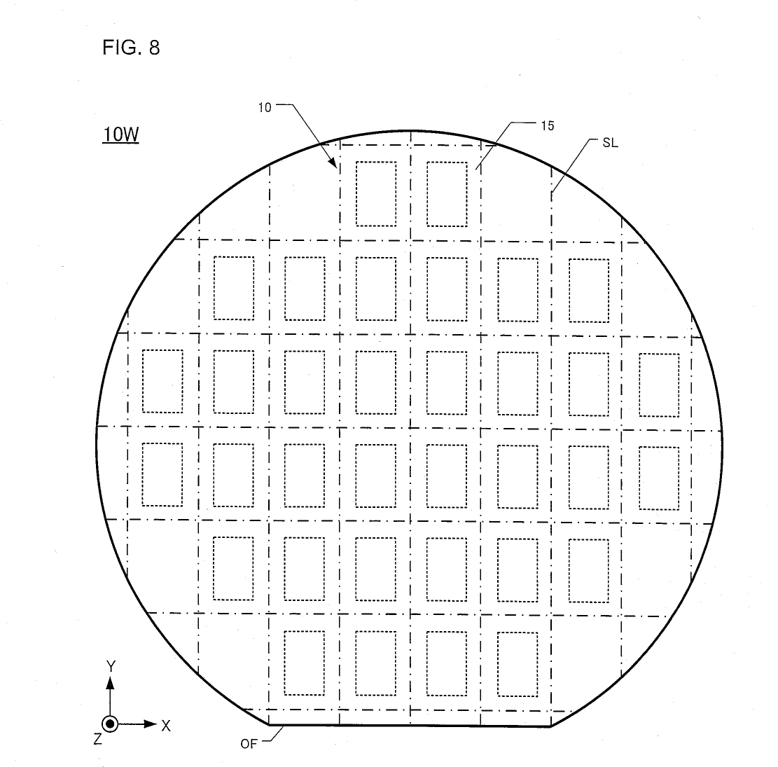

FIG. 8 is a planar schematic view of the lid wafer 10W of the Z-cut crystal substrate. The Z-cut crystal substrate is used as a base material for the lid wafer 10W, and the orientation flat OF is formed in order to specify the crystal orientation on a part of a margin of the lid wafer 10W. A diameter of the lid wafer 10W is also, for instance, three inches or four inches. A plurality of the lids 10 shown in FIG. 3A is formed in the lid wafer 10W. Same as the crystal wafer 20W, even though thirty four lids 10 are formed on the lid wafer 10W in this exemplary embodiment, for the actual manufacturing, hundreds or thousands of the lids 10 can be formed on one wafer. Also, as described in the drawing, a concavity (shown in broken lines) is formed on a surface that faces the crystal wafer 20W on the lid wafer 10W, and the bonding surface 15 is formed around the concavity. The step S01 to the step S03 described in the above are proceeded in no particular order.

In the step S04 of FIG. 5, a bonding step is processed. The bonding process is a process for bonding the base wafer 30W, the lid wafer 10W and the crystal wafer 20W. The base wafer 30W, the lid wafer 10W and the crystal wafer 20W are bonded by a pressure and heat treatment through correctly placing the crystal wafer 20W on the base wafer 30W and placing the lid wafer 10W thereon with the orientation flat OF as a mark. At the same time, the electrode pads 23 of the extracting electrodes 28 formed on the first crystal element 20 and the connection electrodes 32 of the base 30 are also electrically bonded. Meanwhile, the bonding is processed in a vacuum with lower pressure than predetermined pressure or a condition filled with inert gases. Since the periphery of the excitation part 21 is in a vacuum state or filled with inert gas, a stable frequency of the first crystal device 100 can be expected. In the bonding process in this embodiment, the base wafer 30W, the crystal wafer 20W, and the lid wafer 10W are bonded at the same time. However, the invention is not limited thereto, and multiple bonding processes can also be performed. For example, another method is that, after the base wafer 30W and the crystal wafer 20W are bonded, the lid wafer 10W and the crystal wafer 20W are bonded, and so on.

The step S05 in FIG. 5 is a dividing process. In the dividing process, the first crystal devices 100 that are fixed on wafers are cut by a dicing saw or a laser saw along with a line shown as slice lines SL in FIG. 6 to FIG. 8 and divided into hundreds or thousands of the first crystal devices 100.

The manufacturing method of the first crystal device 100 mentioned above describes the case that the first bonding material 51 and the second bonding material 52 are applied on the upper surface of the crystal wafer 20W and the upper surface of the base wafer 30W. However, the first bonding material 51 and the second bonding material 52 can be applied on both of the upper surface and the lower surface of the crystal wafer 20W. Furthermore, the first bonding material 51 and the second bonding material 52 can be applied on the upper surface of the base wafer 30W and the lower surface of the lid wafer 10W.

Although this embodiment describes the Z-cut crystal substrate being used as the base material of the lid wafer 10W and the base wafer 30W, but the AT-cut crystal substrate can also be used. If the AT-cut crystal substrate is used for the lid wafer 10W and the base wafer 30W as the base material, the lid 10 and the base 30 are formed in the same direction as the X-axis, Y′-axis and Z′-axis of the crystal axis of the crystal wafer 20W. Because the lid 10 and the base 30 are formed with the crystal axis that is the same as that of the first crystal element 20, the thermal expansion coefficients in the longer direction of the lid 10 and the first crystal element 20 are the same as those in the longer directions of the base 30 and the first crystal element 20. Furthermore, the thermal expansion coefficients in the shorter direction of the lid 10 and the first crystal element 20 are the same as those in the shorter direction of the base 30 and the first crystal element 20. The first bonding material 51, used in this case, has the same thermal expansion coefficient as that in the longer direction of the first crystal element 20, and the second bonding material 52 has the same thermal expansion coefficient as that in the shorter direction of the first crystal element 20. The break or the frequency variation caused by the temperature change is reduced by forming the first crystal device 100 in the above combination.

Also, a glass substrate can be used as the base material to form the lid wafer 10W and the base wafer 30W. If the glass substrate is used for the lid wafer 10W and the base wafer 30W as the base material, a method is provided to apply the first bonding material 51 that has the same thermal expansion coefficient in the longer direction of the frame 25 of the first crystal element 20 and apply the second bonding material 52 that has same thermal expansion coefficient in the shorter direction of the frame 25 of the first crystal element 20. In addition, the thermal expansion coefficient of the first bonding material 51 can be an intermediate value between the thermal expansion coefficients in the longer direction of the first crystal element 20 and in the longer direction of the glass substrate, and the thermal expansion coefficient of the second bonding material 52 can be an intermediate value between the thermal expansion coefficients in the shorter direction of the first crystal element 20 and in the shorter direction of the glass substrate.

### The Second Embodiment

### The Structure of the Second Embodiment

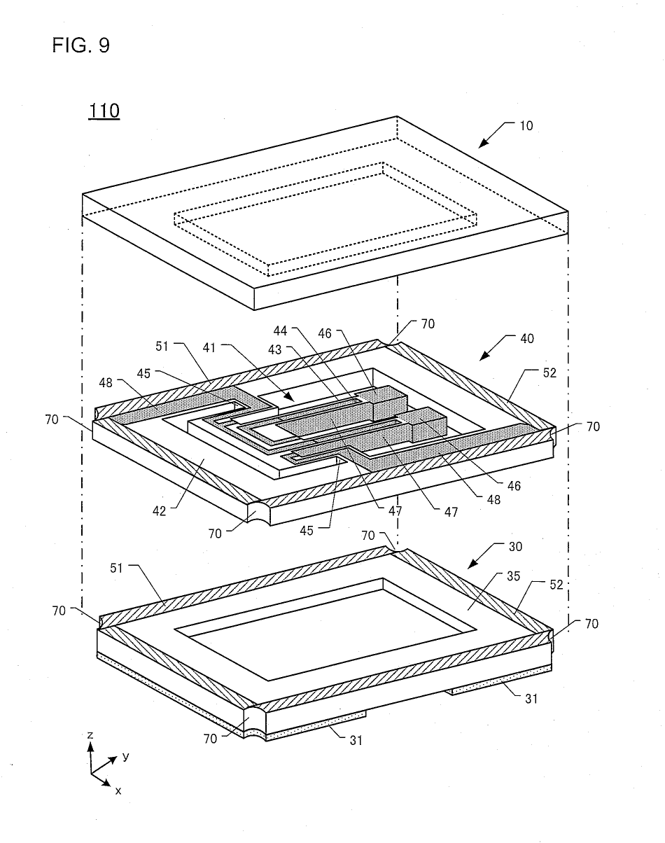

The AT-cut crystal substrate is used for the first crystal element 20 in the first embodiment, but the Z-cut crystal substrate is used for a second crystal element 40 in this embodiment. The second crystal element 40, using the Z-cut crystal substrate as a base material, can be a tuning-fork type. FIG. 9 is an exploded diagram of a second crystal device 110 that uses the second crystal element 40 of the tuning-fork type. As described in the figure, the second crystal device 110 includes the second crystal element 40 of the tuning-fork type, the lid 10 and the base 30. Also, the structure of the second crystal device 110 is the same as that of the first embodiment, except for the second crystal element 40, and their corresponding descriptions are omitted here. In addition, for the same elements, the same reference numerals as the first embodiment are used. Castellations 70 are formed in the second crystal element 40 and the base 30 in the second crystal device 110 of this embodiment. The castellations 70 are through holes in order to electrically connect the external electrodes 31 of the base 30 to the excitation electrodes 47 of the second crystal element 40. The castellations 70 are formed at four corners of the second crystal element 40 and the base 30.

The second crystal element 40 uses the Z-cut crystal substrate as the base material. The second crystal element 40 includes a tuning-fork type crystal vibration unit 41 and a frame 42 surrounding the tuning-fork type crystal vibration unit 41.

The tuning-fork type crystal vibration unit 41 has a pair of vibrating arms 43, and grooves 44 are formed on the front and the back surfaces of each of the vibrating arms 43. The tuning-fork type crystal vibration unit 41 is connected to the frame 42 and connection units 45.

Each vibrating arm 43 extends in width toward the distal ends and has a hammer shape. On a hammer shape portion of the vibrating arms 43, a weight metal film 46 is also formed, and functions as a weight and a frequency adjustment. The role of the weight is situated to generate vibration onto the vibrating arms 43 easily when a voltage is applied to the vibrating arms 43, and stabilize the vibration.

The external shape of the second crystal element 40 and the grooves 44 are formed by using well-known techniques, such as a photolithographic technology and an etching technology, and so on.

The weight metal films 46, the excitation electrodes 47 and the extraction electrodes 48 are then formed on the second crystal element 40 whose external shape and grooves 44 have been formed. The excitation electrodes 47 are formed on the vibrating arms 43 and the grooves 44 of the tuning-fork type crystal vibrating unit 41. When the excitation electrodes 47 are formed, the weight metal films 46 and metal films of the extraction electrodes 48 at the connection units 45 are also formed at the same time.

Similar to the first embodiment, on the frame 42 of the tuning-fork type second crystal element 40, the first bonding material 51 is applied thereon in the longer direction and the second bonding material 52 is applied thereon in the shorter direction. In addition, the applying method for the first bonding material 51 and the second bonding material 52 is the same as the first embodiment.

The same as the first embodiment, the lid 10 and the base 30 can use the Z-cut crystal substrate, the AT-cut crystal substrate, or the glass substrate as their base material.

When the Z-cut crystal substrate is used for the lid 10 or the base 30 as the base material, preferably, the Z-cut crystal substrate is formed to consist with the crystal axis of the second crystal element 40 of the tuning-fork type. Also, a bonding material is preferably chosen as the first bonding material 51 to have the same expansion coefficient as that in the longer direction of the second crystal element 40 of the tuning-fork type. Besides, a bonding material is preferably chosen as the second bonding material 52 to have the same expansion coefficient as that in the shorter direction of the tuning-fork type second crystal element 40.

When using the AT-cut crystal substrate or the glass substrate as the base material of the lid 10 or the base 30, as one of the methods, a bonding material is chosen as the first bonding material 51 to have the same thermal expansion coefficient as that in the longer direction of the frame 42 of the tuning-fork type second crystal element 40, and a bonding material is chosen as the second bonding material 52 to have the same the thermal expansion coefficient as that in the shorter direction of the frame 42 of the second crystal element. On the other hand, according to another method, a bonding material that has a thermal expansion coefficient the same as an intermediate value between the thermal expansion coefficients in the longer direction of the second crystal element 40 of the tuning-fork type and in the longer direction of the AT-cut crystal substrate or the glass substrate can be chosen as the first bonding material 51. Also, a bonding material that has a thermal expansion coefficient the same as an intermediate value between the thermal expansion coefficients in the shorter direction of the second crystal element 40 of the tuning-fork type and in the shorter direction of the AT-cut crystal substrate or the glass substrate is chosen as the second bonding material 52.

Although the invention has been described with reference to the above embodiments, it will be apparent to one of the ordinary skill in the art that modification to the described embodiments may be made without departing from the spirit of the invention.

### DESCRIPTION OF REFERENCE NUMERALS

| | | | |
|---|---|---|---|
| 10 | lid | 10W | lid wafer |
| 11 | ceiling surface | | |
| 15 | bonding surface | | |
| 20 | first crystal element, | 20W | crystal wafer |
| 21 | excitation part | | |
| 22 | opening | | |
| 24 | connection part | | |
| 25 | frame | | |
| 27 | excitation electrode, | 28 | extracting electrode |
| 30 | base | 30W | base wafer |
| 31 | external electrodes, | 32 | connection electrodes |
| 33 | bottom side | | |
| 35 | frame | | |
| 36 | bonding surface | | |
| 40 | second crystal element | | |
| 41 | crystal vibration unit of | | |
| | a tuning fork type | | |
| 42 | frame | | |
| 43 | vibrating arms | | |
| 44 | groove | | |
| 45 | connection units | | |
| 46 | weight metal film | | |
| 47 | excitation electrode | | |
| 48 | extracting electrode | | |
| 51 | first bonding material | | |
| 52 | second bonding material | | |
| 61 | first applying area | | |
| 62 | second applying area | | |
| 70 | castellations | | |
| 100 | first crystal device | | |
| 110 | second crystal device | | |
| Au | gold layer | | |
| Cr | chrome layer | | |
| SL | slice line | | |

What is claimed is:

1. A crystal device comprising:
a crystal element, having a rectangular shape, formed by a crystal material comprising an excitation part that vibrates when voltage is applied and a frame that surrounds the excitation part, wherein the frame comprises sides respectively along a first direction and a second direction intersected with the first direction;
a base, having a rectangular shape, bonded to a principal plane of the frame and comprising sides respectively along the first direction and the second direction; and
a lid, having a rectangular shape, bonded to another principal plane of the frame and comprising sides respectively along the first direction and the second direction,
wherein a first bonding material that corresponds to a thermal expansion coefficient in the first direction of the crystal element is applied on each side of the frame, the base and the lid along the first direction, and
a second bonding material that is different from the first bonding material and corresponds to a thermal expansion coefficient in the second direction of the crystal element is applied on each side of the frame, the base and the lid along the second direction.

2. The crystal device of claim 1, wherein the first bonding material has a thermal expansion coefficient that is equal to a thermal expansion coefficient in the first direction of the crystal element, or equal to an intermediate value between a thermal expansion coefficient in the first direction of the crystal element and a thermal expansion coefficient in the second direction of the base and the lid, and
the second bonding material has a thermal expansion coefficient that is equal to a thermal expansion coefficient in the second direction of the crystal element, or equal to an intermediate value between a thermal expansion coefficient in the second direction of the crystal element and a thermal expansion coefficient in the second direction of the base and the lid.

3. The crystal device of claim 1, wherein the crystal element is an AT-cut crystal material, and
the base and the lid are the AT-cut crystal material, a Z-cut crystal material, or a glass material.

4. The crystal device of claim 2, wherein the crystal element is an AT-cut crystal material, and
the base and the lid are the AT-cut crystal material, a Z-cut crystal material, or a glass material.

5. The crystal device of claim 1, wherein;
the crystal element is the Z-cut crystal material, and
the base and the lid are the AT-cut crystal material, the Z-cut crystal material, or the glass material.

6. The crystal device of claim 2, wherein;
the crystal element is the Z-cut crystal material, and
the base and the lid are the AT-cut crystal material, the Z-cut crystal material, or the glass material.

7. The crystal device of claim 1, wherein;
the first bonding material and the second bonding material are a polyimide resin, or a glass with a melting point below 500° C.

8. The crystal device of claim 2, wherein;
the first bonding material and the second bonding material are a polyimide resin, or a glass with a melting point below 500° C.

9. The crystal device of claim 3, wherein;
the first bonding material and the second bonding material are a polyimide resin, or a glass with a melting point below 500° C.

10. The crystal device of claim 4, wherein;
the first bonding material and the second bonding material are a polyimide resin, or a glass with a melting point below 500° C.

11. The crystal device of claim 5, wherein;
the first bonding material and the second bonding material are a polyimide resin, or a glass with a melting point below 500° C.
